(19) United States
(12) Patent Application Publication
(10) Pub. No.: US 2015/0249178 A1
(43) Pub. Date: Sep. 3, 2015

(54) Solar Power System

(71) Applicant: OVERTONE SOLAR LTD, London (GB)

(72) Inventor: James Norman, London (GB)

(21) Appl. No.: 14/427,110

(22) PCT Filed: Jul. 18, 2013
(86) PCT No.: PCT/GB2013/051929

§ 371 Date: Mar. 10, 2015

(30) Foreign Application Priority Data
Sep. 11, 2012 (GB) 1216135.2
Oct. 26, 2012 (GB) 1219294.4
Jan. 22, 2013 (GB) 1301126.7

(51) Int. Cl. H01L 31/054; H02S 30/10; H02S 40/42

(52) U.S. Cl. CPC H01L 31/0547; H02S 40/42; H02S 30/10

(57) ABSTRACT

An apparatus for generating electrical energy from light energy, the apparatus comprising: a plurality of directing means, wherein each directing means is configured to receive light energy in a first direction and redirect said light energy in a second direction, wherein the light energy in the first direction is emitted from a light source; receiving means configured to receive light energy in the second direction from each directing means; and conversion means configured to directly convert the light energy received in the second direction into electrical energy.

The present invention relates to an apparatus for generating power or electricity from light energy such as solar radiation, and a method of using the same.

It is a well known problem that the availability of fossil fuel resources which are currently used to supply the world's energy demands are rapidly depleting. As such, the search for other sources of energy which may be used instead of those requiring the destruction of natural resources is underway. These new sources, termed renewable energy resources, such as wind, wave, geothermal, or solar power and the like, are intended to harvest energy from the environment that is already present, without consumption of non-replaceable materials. Of these renewable resources, solar power offers the greatest opportunity for the generation of large amounts of energy given the high intensity of the solar radiation received by many parts of the earth.

Existing apparatuses for generating power or electricity from high intensity light energy, such as solar radiation, typically comprise a series of reflecting elements adapted to receive light from a source and reflect it several times in such a way that the light energy is concentrated onto a particular receiving element. The receiving element typically comprises means to transfer such light energy to an energy storage element such as a heat conductor, which may be formed from a variety of conductive materials, for example water, ionic solutions or metals. The energy stored in the storage element is then either used directly, for example as heated water, or converted to electricity for supply to the consumer. Such apparatuses require the use of a number of reflections to concentrate the light energy onto a receiving element, causing losses in the energy of the light at each reflection, for example by heat transferred to the reflecting element itself. Similarly, the use of an energy storage element means that the light energy has to be further transformed into heat energy and mechanical energy before it can then be transformed to electrical energy. At each stage of transformation, energy losses occur, making such apparatuses inefficient and undesirable for mass market energy supply. Furthermore, complexities due to the number of component parts are an economical barrier to the widespread use of such solar power apparatuses.

The use of piezoelectric materials in such apparatuses has also been developed. Piezoelectric materials are able to achieve the transformation of stored heat energy into electricity via mechanical deformation. Piezoelectric or pyroelectric materials rely on a change in temperature to cause a mechanical deformation in the material which generates an electric current. Typically, in order to enable a constant supply of electricity from such materials, several piezoelectric or pyroelectric materials are used, to which the stored energy is transferred in periodic intervals such that at each point in time at least one piezoelectric or pyroelectric element is undergoing a change in temperature. The use of piezoelectric or pyroelectric materials has substantially improved the solar power apparatuses in use today, however their properties have not yet been optimised to allow the maximal possible output of electricity from the light energy received into such apparatuses.

It is an object of at least some of the aspects of the present invention to address the above mentioned disadvantages. More particularly, it is an object of the present invention to improve the all round efficiency of solar power apparatuses, and optimise the output of piezoelectric or pyroelectric materials within such a apparatus, whilst maintaining a simple arrangement of components.

According to a first aspect of the present invention, there is provided an apparatus for generating electrical energy from light energy, comprising:
a plurality of directing means, wherein each directing means is configured to receive light energy in a first direction and redirect said light energy in a second direction, wherein the light energy in the first direction is emitted from a light source;
receiving means configured to receive light energy in the second direction from each directing means; and
conversion means configured to directly convert the light energy received in the second direction into electrical energy.

Advantageously, the present apparatus minimises the number of reflections of the light energy from the source to the receiving means, and minimises the number of energy transformations for the light energy to be converted to electrical energy, such that the energy transfer in the apparatus is as direct as possible. Accordingly, the present apparatus increases the efficiency of harvesting energy from light, and provides a more simplistic arrangement of components for doing so.

Preferably the directing means comprises one or more reflectors.

Suitably, therefore, each directing means receives the light energy in a first direction and redirects said light energy in a second direction by reflection.

Preferably the one or more reflectors are formed from mirrored material, for example mirrored glass; polished metal such as, but not limited to, copper, steel, aluminium, silver; or silvered polymers.

Optionally the reflectors may be formed from a laminate of one or more of the abovementioned mirrored materials. Preferably such a laminate comprises thin films of the relevant mirrored material in order to reduce the manufacturing cost and weight of the reflectors.

Preferably the reflectors are covered with a layer of protective glass.

Optionally, the one or more reflectors may be ridged in order to improve the strength to weight ratio of the reflectors. Advantageously, the inherent strength of the reflectors reduces the support needed and thereby the weight of the reflectors.

Suitably, the one or more reflectors are arranged to focus light energy to a focal point.

Suitably, therefore, the one or more reflectors focus the light energy in a second direction to a focal point. Suitably the focal point is on the receiving means.

Preferably the one or more reflectors are arranged on a first reflector support. More preferably the reflectors are arranged on a facing surface of the first reflector support, wherein the facing surface faces towards the receiving means. Preferably the facing surface is a substantially concave surface to aid focussing of the light energy in a second direction.

Preferably the one or more reflectors are arranged on the facing surface of the first reflector support in an array. Preferably the array comprises between 4 and 25 reflectors. The one or more reflectors may be arranged as an array of parallel rows of individual reflectors, radial circles of individual reflectors, a tessellating pattern of individual reflectors, or any other suitable arrangement.

Preferably, the one or more reflectors present upon a single directing means are arranged to focus the light energy in a second direction to the same focal point on the receiving means.

However, preferably each of the directing means is arranged to focus the light energy in a second direction to a slightly different focal point on the receiving means such that the light energy in a second direction is evenly distributed over the surface of the receiving means.

Suitably, therefore, each of the reflectors present on each of the plurality of directing means is adjustable, such that the correct angle of reflection may be set in order to allow each directing means to focus the light in a second direction onto the same focal point on the receiving means. The correct angle of reflection taking account of the distance to the point of focus on the receiving means, the position of the light source, and the latitude of the apparatus.

Preferably, each of the directing means is capable of adjusting regularly to take account of a moving light source. More preferably each of the directing means is capable of ‘tracking’ the light source. Suitably, therefore, each of the directing means is adjusted such that the light in a first direction received from the light source is consistently reflected and focussed in the second direction by the reflectors, to the same point on the receiving means regardless of the position of the light source.

Preferably, each of the directing means adjusts every few minutes to take account of the motion of the light source, more preferably the directing means adjusts once a minute, still more preferably directing means adjusts once every 0.01-50 seconds to take account of the motion of the light source.

Preferably each of the reflectors present on each of the plurality of directing means is sized such that the light source takes up the entire reflector when viewed from the receiving means, and therefore no unnecessary ambient reflection takes place.

Preferably the plurality of directing means are arranged as a field of directing means. Preferably the field consists of at least 50 directing means, more preferably at least 100 directing means, still more preferably at least 500 directing means. Preferably the field comprises the directing means arranged in rows, more preferably in parallel rows, with the reflectors facing towards the receiving means. Preferably the rows are offset relative to one another.

Alternatively, the plurality of directing means may be arranged in concentric circles, arcs or semicircles, with reflectors facing towards the receiving means.

Optionally, some of the plurality of directing means may comprise a second reflector support with further reflectors arranged upon it as described for the first reflector support. Preferably the reflectors on the second reflector support comprise a different second focus point to that of the reflectors on the first reflector support. Preferably the two focus points are set such that the reflectors on the first reflector support focus light to a relatively near point and the reflectors on the second reflector support focus light to a relatively far point, for example. Advantageously, this feature enables directing means of apparatuses positioned in very Northern or Southern latitudes or at extreme edges of the field, where there is a wide variation in distances to the focus point, to be adjusted quickly and easily by use of either the first or second reflector support to reflect light in a second direction.

Preferably the light source used in the present apparatus is the sun, and therefore the light energy emitted from said light source is solar radiation.

Accordingly, preferably each of the directing means is capable of adjusting regularly so as to track the sun across the sky in such a way that maintains a consistent reflection of light received in the first direction to a second direction, wherein the light in second direction reflected from each directing means remains focussed to the same point on the receiving means throughout the day.

Preferably each of the directing means is adjusted by movement of the first and/or second reflector support comprising the one or more reflectors. Still more preferably, each of the directing means is adjusted by movement of the facing surface of the first and/or second reflector support comprising the one or more reflectors.

Preferably, the directing means is capable of being adjusted by movement in at least the axial direction, and by rotation around the x, y and z axes.

Suitably, therefore the directing means as a whole are adjustable as are the individual reflectors present upon the directing means.

Suitably, the receiving means is formed from a surface material capable of receiving and absorbing light energy, and an insulating material.

Preferably the surface material is composed of a conductor which is able to conduct electricity and heat, yet which has a high conductivity to weight ratio. More preferably the surface material is selected from, for example: pyrolytic carbon, graphite aluminium, or graphene.

Preferably, the surface material is able to absorb light energy at least across the range of optical, infrared and UV wavelengths. Optionally, the surface material may be coated to enhance absorption, for example a carbon nanotube coating may be used.

Suitably the surface material absorbs the light energy received in a second direction which heats the surface material, which heat is then directly transferred to the conversion means. Advantageously, the surface material is able to heat and cool easily, absorb light energy and transfer the associated heat to the conversion means, and also provide the principal electrical conductor for the generated electrical energy to an output.

Preferably the insulating material surrounds the surface material. More preferably the insulating material is positioned around and beneath the surface material in order to avoid any loss of heat, or shorting of electrical energy between receiving means. Preferably the insulating material is formed from materials comprising a low thermal conductivity and a low electrical conductivity, for example mica.

Preferably the receiving means comprises at least a first receiving portion and a second receiving portion formed from the materials described above.

Preferably the first and second receiving portions are arranged to alternately receive the light energy in the second direction from the directing means. Preferably therefore, the plurality of directing means direct the light in the second direction onto the first receiving portion for a certain time interval, and then direct the light in the second direction onto the second receiving portion for a certain time interval. Suitably, therefore, the light in the second direction oscillates between being focussed on the first and second receiving portions.

Suitably, the time interval spent by the light in the second direction on each receiving portion is adjustable depending on the intensity of the light emitted from the light source, the amount of light emitted from the light source, the weather and any other relevant factors. However typically, the time interval is between 0.005-100 seconds, more preferably 0.005-50 seconds, most preferably 0.005-25 seconds.

In a particularly preferred embodiment, the time interval spent by the light in the second direction on each receiving portion may extend as low as around 0.0025 seconds.

Typically therefore, a complete oscillatory cycle of the light in the second direction between the first and second receiving portions is between 0.01-200 seconds, more preferably 0.01-100 seconds, most preferably 0.01-50 seconds.

In a particularly preferred embodiment, therefore, a complete oscillatory cycle of the light in the second direction between the first and second receiving portions may extend as low as around 0.005 seconds.

Preferably the light in the second direction is directed by movement of the reflectors present on each of the directing means (as described above) to change the point of focus to alternate between the first and second receiving portions.

Suitably, therefore movement of the directing means encompasses both movement to alternate the point of focus between the first and second receiving means, as well as movement to take account of the motion of the light source.

Alternatively, the point of focus of the light energy in the second direction may be alternated between the first and second receiving portions by movement of the receiving portions themselves. Movement of the receiving means is described in the relevant section below.

In a further alternative embodiment, the light in the second direction may be directed by movement of an intermediate reflector, which may be positioned between the directing means and the receiving means to change the point of focus to alternate between the first and second receiving portions.

Preferably, each of the receiving means is adjustable. Preferably each of the receiving means is capable of being adjusted by movement in at least the axial direction, and by rotation around the x, y and z axes. Advantageously, this flexibility allows not only the directing means to be adjusted but also the receiving portions to be adjusted such that there are two mechanisms to keep the focus point of the light in a second direction upon the relevant receiving portion. The receiving means may also be adjusted axially, in particular by raising or lowering, to maintain the most optimal angle towards the majority of the directing means. Furthermore, such adjustability allows the movement of the receiving portions to occupy different facing positions, such that one receiving portion may serve to receive light from several different fields of directing means, thereby reducing the number of receiving means needed and increasing the efficiency of the apparatus.

Preferably, the receiving means are rotated. More preferably the receiving means are rotated around their y axis. Preferably the receiving means are rotated around their y axis constantly. Preferably the receiving means are rotated around their y axis at a multiple of the periodic frequency of the oscillation of the light in the second direction between the at least two receiving portions. Advantageously, this ensures an even distribution of the light in a second direction upon the surface of the receiving means. Optionally the rotation of the receiving means may be adjustable such that the rotation can be set off-axis in order to allow for misalignment of different receiving means or misalignment of the focus point of the light in the second direction.

Suitably, the arrangement of the receiving means relative to the directing means is adapted to the environment in which the apparatus is to be used in order to maximise captured light energy. For example, preferably in equatorial environments, the apparatus is arranged such that the receiving means is located in the centre of the field of directing means. However, preferably in northern or southern latitudes, multiple receiving means are located around the edges of the field of directing means, and preferably the number of receiving means in use at any one time can be varied depending on the season.

The receiving means may optionally further comprise light shield. Preferably the light shield is hemispherical. Preferably the hemispherical light shield is positioned between the receiving means and acts to reflect any unfocussed light energy that has been misdirected by the directing means, back towards the surface material of the receiving means or the field of directing means. Preferably therefore the light shield is formed from a reflective material.

Advantageously the light shield further allows the light in the second direction to lag behind the movement of the directing means when moving between the first and second receiving portions, such that not all of the light in the second direction is received at the same time by the relevant receiving portion. This causes the receiving portion to heat up at a linear rate and avoids a spike in temperature as the receiving portion receives the light.

Preferably the conversion means is formed from any material capable of converting light energy into electrical energy. More preferably, the conversion means is formed from any material capable of converting light energy into electrical energy via a temperature change, such as, but not limited to, piezoelectric or pyroelectric materials. Most preferably, the conversion means is formed from any crystalline or polymeric crystalline piezoelectric or pyroelectric material, such as, for example: lithium tantalite, piezoelectric graphene, polyvinyldiflouride, lithium niobate, barium tantalite, lead zirconate or lead titanate.

Preferably the material forming the conversion means is a conversion material, therefore the conversion material may be formed from any material capable of converting light energy into electrical energy via a temperature change, such as, but not limited to, piezoelectric or pyroelectric materials. Preferably, the conversion material is formed from any crystalline or polymeric crystalline piezoelectric or pyroelectric material as defined above.

More preferably, the conversion material is formed from piezoelectric graphene which may be crystalline or amorphous. Most preferably, the conversion material is formed from crystals of piezoelectric graphene.

Optionally the piezoelectric graphene may be polarised, and may therefore be termed a dielectric, suitably dielectrics are good electrical insulators, therefore preferably the polarised piezoelectric graphene is operable to insulate itself from any conductive material.

Optionally the piezoelectric or pyroelectric material may be present as a single crystal, an array of crystals, a stack of crystals or any combination thereof, for example an array of crystal stacks.

In the case where a piezoelectric conversion means is used, preferably the surface material of the receiving element is tensioned such that any expansion of the surface material is directly transferred to the conversion means. More preferably the surface material is tensioned in an arcuate shape.

In the case where a pyroelectric conversion means is used, preferably the surface material of the receiving element is designed as a heat sink such that the heating of the surface material is retained and directly transferred to the conversion means. For example, the surface material may be undulated.

In any case, preferably the surface material of the receiving means comprises a grain which is directed towards the piezoelectric or pyroelectric conversion means in order to aid the transfer of heat between the surface material and the conversion means.

In a particularly preferred embodiment, the surface material is periodically patterned graphene, preferably when piezoelectric graphene forms the conversion means. The dielectric may be periodically patterned grapheme.

In a particularly preferred embodiment, the conversion means is integral to the receiving means of the apparatus. More preferably the receiving means comprises the conversion means, such that the receiving means and conversion means are effectively a single one-piece component. Accordingly, preferably the light received by the surface material of the receiving means is transmitted directly to the conversion means. In such an embodiment, preferably the surface material of the receiving means overlies the conversion means.

Optionally, in such an embodiment, the surface material may overlay both sides of the conversion means such that a sandwich type arrangement is produced with a central conversion means surrounded by surface material. Advantageously, this arrangement allows light energy to be absorbed by the surface material on both sides of the receiving means. Therefore one receiving means may act to receive light energy from more than one field of directing means, decreasing the number of components in the apparatus and increasing the light energy captured.

In such an embodiment, preferably the conversion means is rotated together with the receiving means in a manner as explained above for the receiving means. Preferably therefore, the electrical connection between the conversion means and a power output line is achieved by the use of conductive brushes. More preferably the conductive brushes are carbon brushes. The conductive brushes may be static or may also rotate, but preferably they are in contact with the surface material of the receiving means such that the electrical energy may be conducted from the conversion means to the brushes. More preferably the conductive brushes are in contact with the reverse of the surface material of the receiving means, the reverse being the side not receiving light in the second direction.

Alternatively, in other embodiments, the electrical connection between the conversion means and a power output line may be achieved by the use of induction. Preferably the inductive energy transfer is accompanied by a simultaneous voltage step down.

Optionally, the conversion means is polarised horizontally such that the direction of polarisation extends laterally across each of the receiving portions. Preferably therefore the sides of each receiving portion are electrically conductive.

Alternatively, the conversion means is polarised vertically such that the direction of polarisation extends longitudinally across each of the receiving portions. Preferably therefore the ends of each receiving portion are electrically conductive. Preferably therefore the end of each connector is formed from an electrical conductor.

Preferably the generated electricity is conducted away from the sides or ends of the receiving portions by the use of conductive brushes suitably in contact with the conversion means as described hereinabove.

Piezoelectric or pyroelectric materials convert mechanical stress caused by a change in temperature into electrical energy. Accordingly, in order to produce electrical energy, the material must be either heating or cooling. Advantageously, the present invention utilises this property to produce electrical energy at a twice the efficiency than previously exploited in similar apparatuses.

As the light energy in the second direction oscillates its point of focus between at least the first and second receiving portions, one of the receiving portions is receiving and absorbing the light energy and heating, whilst the other is not receiving any light energy and is cooling. Accordingly, at any point in time, one receiving portion is heating (expanding) and one is cooling (contracting), meaning both receiving portions are undergoing a change in temperature which thereby causes a change in mechanical stress of the conversion means, and causes generation of electrical energy from both receiving portions in a constant manner.

Preferably the apparatus further comprises a cooling means.

Preferably the cooling means consists of a fan. More preferably the cooling means consists of a centrifugal fan or an axial fan.

Preferably the cooling means acts to cool the receiving means. More preferably the cooling means acts to alternately cool the first and second receiving portions of the receiving means. Still more preferably the cooling means acts to cool the first and second receiving portions of the receiving means in antiphase to the light energy received by the first and second receiving portions. Such that, for example, when the first receiving portion is receiving light, the second receiving portion is being cooled, and when the second receiving portion is receiving light, the first receiving portion is being cooled.

Preferably the cooling means is positioned at the centre, between the at least two receiving portions, such that the at least two receiving portions are radially displaced from the cooling means.

Preferably the cooling means comprises a flow director configured to direct the cooling onto either of the first or second receiving portions at any one time. Preferably the flow director is either a rudder or a rotating outlet such as a vent. More preferably the flow director is a vent operable to rotate circumferentially around the cooling means, particularly a cooling means which comprises a centrifugal fan.

Preferably the cooling means further comprises a sleeve configured to shield the same first or second receiving portion being cooled. Advantageously, the sleeve enhances the direction of the cooling from the flow director onto the desired receiving portion, and further shades the relevant receiving portion from any further ambient light and heat which would detract from the cooling. The sleeve may be optionally provided with air ducts to allow the passage of cooling air there through.

Preferably the sleeve is configured to rotate. More preferably the sleeve is configured to rotate such that the sleeve continuously moves from covering the first receiving portion being cooled to covering the second receiving portion being cooled in a cyclic manner. Preferably the sleeve rotates at a speed which is equivalent to the period of oscillation of the cooling means and the light in the second direction, such that one full rotation of the sleeve is equivalent to one full oscillation of the cooling means. Preferably, therefore, the sleeve rotates such that it is in-phase with the oscillation of the cooling means, and in antiphase to the oscillation of the light in the second direction.

Preferably the apparatus uses some of the electrical energy generated to drive the movement of the components of the apparatus, preferably the movement of the sleeve or receiving means, more preferably the rotation of the sleeve or receiving means. For example by using high voltage switches such as Field Effect Transistors, part of the electrical energy generated by the conversion means is diverted to directly drive the movement of the apparatus. For example by using electromagnets arranged around the apparatus in a similar way to a stepper motor.

Preferably the rotational part of the apparatus, for example the sleeve or receiving means, rests on bearings or magnetic bearings, advantageously reducing friction.

In one preferred embodiment, the flow director is a rotatable vent that preferably rotates in phase with the rotation of the sleeve to direct cooling air from the cooling means under the sleeve to the covered receiving portion. Preferably therefore the vent comprises a plurality of actuators capable of mounting the vent to the sleeve.

Optionally, the actuators may also be adjustable such that they may extend or collapse. Preferably the actuators may extend so as to raise the sleeve outwardly away from the surface of the receiving portion, and may collapse so as to lower the sleeve inwardly towards the surface of the receiving portion. Advantageously, the cooling effect from the cooling means may be increased or decreased by the motion of the actuators inwards and outwards respectively.

Alternatively the sleeve may be stationary and actuators may extend or collapse independently of the sleeve.

Alternatively, the cooling means may be formed from high accuracy shutters which are held very close to the first or second receiving portion using high accuracy actuators and preferably comprising a heat retaining material.

Preferably the sleeve comprises a shape that gradually increases the cooling effect applied across the receiving portion being cooled. More preferably, the sleeve is a scythe or triangular shape.

Advantageously, the cooling means acts to further reduce the temperature of the receiving portion not receiving any light energy in the second direction, thereby increasing the temperature difference experienced by the receiving means when receiving the light and when not receiving the light. By increasing this difference, there is an increase in the mechanical stress applied to the conversion means and an increase in the output of electrical energy produced.

Preferably the heating and cooling zones are maintained at temperature and where appropriate, thermally separate from each other by mechanisms well known in the art. For example using thermal insulation, vacuum insulation, cooling pipes containing liquid or gas, enclosures, reflectors or any combination thereof. Preferably the thermal separation is achieved by the use of reflectors. In one embodiment, the cooling zones are maintained at temperature by the use of a fluid flow of cold air, preferably over the surface of the receiving portions present in the cold zone.

Preferably energy dissipating from the reflectors may be harvested. Preferably using a thermodynamic process, such as a steam turbine. Preferably energy dissipating in the reflectors may be reintroduced into the system. Preferably this reintroduction may be arranged via air flow or liquid flow. Preferably this reintroduction may be made more efficient by using heatsinks.

Optionally, the cooling means may act in a trimode manner. Instead of simply oscillating between the two alternate states of cooling the first and second receiving portions of the receiving means, the cooling means may comprise a further mode wherein the cooling means is directed at none of the receiving means. Advantageously, this may allow time for the temperature of the receiving means to change fully before cooling takes place, since the temperature of the surface material and the conversion means is likely to lag behind the actual temperature being applied across the surface material.

In a particularly preferred embodiment, the conversion material forming the conversion means is alternately heated and cooled by movement of the conversion means together with the receiving means. More preferably the conversion material in the conversion means is moved through alternate heating and cooling zones. Advantageously, this enables the conversion material to act pyroelectrically or piezoelectrically and generate electricity constantly when in both the heating and the cooling zones. Thereby maximising the voltage output of the conversion means.

Preferably, in such an embodiment, the conversion material in the conversion means is arranged in a ring, preferably the ring rotates, more preferably the ring rotates through the heating and cooling and zones, therefore the conversion material is preferably moved by rotation through said zones.

Preferably the ring comprises an inner ring and an outer ring.

Preferably the conversion material is composed of strips, preferably strips of thin film. Preferably the thin film is applied to a substrate, preferably the substrate is graphene, or piezoelectric graphene. Preferably the strips are between around 50 mm and 200 mm in length, more preferably 75 mm and 150 mm, still more preferably 90 mm and 110 mm, most preferably 100 mm in length. Preferably the strips are between around 1 nm and 5 nm in depth, more preferably 2 nm and 4 nm, still more preferably 2.5 and 3.5 nm, most preferably 3.3 nm in depth.

In one embodiment, conversion material forming the conversion means is piezoelectric graphene and the substrate is graphene.

In an alternative embodiment, the conversion material forming the conversion means is PVDF, and the substrate is graphene or piezoelectric graphene.

Preferably the strips of conversion material are arranged in the ring such that they extend preferably from the inner ring, more preferably from the inner ring in a radial arrangement, still more preferably from the inner ring in a radial arrangement to the outer ring.

Suitably therefore, the strips of conversion material comprise two ends, an inner end and an outer end. The inner end being proximal to the inner ring and the outer end being proximal to the outer ring.

Preferably the strips of conversion material are connected at both ends to the inner and outer ring by connectors.

Preferably the connectors are able to compensate for the expansion and contraction of the conversion material. Preferably the connectors are able to predictively compensate for the expansion and contraction of the conversion material. The connectors may comprise any elastically deformable component, such as, for example, springs, or rubber. However, preferably the connectors comprise a piezoelectric material working in antiphase to the expansion and contraction of the conversion material within the conversion means. Alternatively, the connectors comprise electromagnets.

Preferably, in any case, the receiving portions comprise one or more moveable connectors such that they may be tethered at any edge, side and/or end. The moveable connectors may comprise one or more springs or actuators, preferably piezoelectric or electromagnetic actuators as described hereinabove. Preferably the springs/actuators are tuned to the resonant frequency or a multiple thereof of the receiving portion, more preferably to the resonant frequency or a multiple thereof of the conversion material of the receiving portion.

Optionally the or each connector may also be used to manually or automatically tune the springs/actuators and/or the receiving portions to the resonant frequency thereof.

Preferably the heating zones are provided by solar radiation, more preferably by concentrated solar radiation as explained hereinabove.

Preferably the concentrated solar radiation is concentrated by about 22 to 600 times the average solar radiation received at ground level on earth, more preferably by 45 to 300 times, still more preferably by 90 to 150 times, most preferably by about 117.5 times.

Preferably the cooling zones are provided by an airflow, more preferably a fan generated airflow, wherein the fan may be a centrifugal or axial fan as described hereinabove. Preferably the airflow is directed across the surface of the conversion material.

Preferably the movement of air within the air cavity is arranged perpendicular to the airflow generated by rotation of the receiving means, thereby creating a tangential airflow of higher velocity and longer length across the receiving means thus creating a greater cooling effect as a result.

Preferably the airflow is of a speed of between 200 m/s and 5 m/s, more preferably between 150 m/s and 15 m/s, still more preferably between 120 m/s and 20 m/s, most preferably 95 m/s.

Preferably the ring of conversion material is rotated through the heating and cooling zones at a frequency of heating and cooling of between 5,672 and 90,752 Hz, wherein the conversion material length (D), i.e. the length of each strip of the conversion material, is proportion to the speed of sound through the material (v) and inversely proportional to the frequency (0 as given by the following formula:

More preferably the ring is rotated through the heating and cooling zones at a frequency of heating and cooling of between 20,000 and 5,000 Hz, more preferably between 15,000 and 7,000 Hz, still more preferably between 12,000 and 10,000 Hz, most preferably between 11,344 Hz to 5,672 Hz.

Preferably, in such an embodiment, the number of heating and cooling zones per rotation is between 1 and 96, more preferably between 4 and 48, still more preferably between 8 and 24.

Preferably the conversion material is sized such that each strip of the conversion material will resonate at or near the frequency of heating and cooling as defined above, for example, when the material is Lithium Tantalate, a length of around 100 mm by around 3.3 nm depth per strip is suitable.

Preferably, each strip of the conversion material corresponds to one discrete crystal of said material.

Preferably the resonant frequency of the conversion material is in the longitudinal mode or flexural mode of the conversion material, more preferably the resonant frequency of the conversion material is in the longitudinal mode of the conversion material.

Preferably the frequency of heating and cooling is at, or near to, the fundamental resonant frequency of the conversion material, or a harmonic thereof. More preferably the frequency of heating and cooling is at, or near, the first harmonic of the resonant frequency of the conversion material.

Advantageously, it has been found that maintaining the frequency of heating and cooling of piezoelectric or pyroelectric materials, such as those used as the conversion material, at frequencies which are at, or near to, the fundamental frequency of the material, provides an increased voltage output.

Therefore, most preferably the frequency of heating and cooling is at, or near to, the first harmonic of the resonant frequency of the conversion material.

Advantageously, use of the conversion material within the conversion means in this rotating manner under resonance increases the dipole moment within the conversion material structure, thereby increasing the amount of output voltage generated. Matching the frequency of the heating and cooling experienced by the conversion material to the resonant frequency of the conversion material itself causes the output voltage produced to increase by up to 16 times and has a similar effect on the current produced. It will increase the current such that the current will tend to infinite as the frequency of heating and cooling reaches the resonant frequency of the conversion material or a harmonic thereof.

Optionally the apparatus may further comprise heat sinks to aid the cooling means. Preferably the heat sinks are positioned beneath and/or around the receiving means. More preferably the heat sinks are positioned beneath the surface material of the receiving means. Still more preferably the heat sinks are positioned beneath the surface material of the receiving means, and between the surface material and the conversion means. Advantageously, such a position allows the heat sink to increase the quality of connection between the surface material and the conversion means.

Optionally the surface material of the receiving means may also comprise apertures to increase the available surface area for cooling.

Preferably the apertures extend not only through the surface material, but also throughout the receiving means. Preferably the apertures are present in each layer of the surface material such that the apertures are substantially overlapping.

Preferably the apertures comprise a diameter which matches the wavelength of light to be absorbed, advantageously acting as wave receivers. The apertures may optionally increase or decrease in diameter through the depth of the receiving means, varying in diameter according to the range of wavelengths to be absorbed. Preferably the apertures are spaced equidistantly apart. Preferably alternate apertures vary in diameter in opposing directions, one increasing in diameter the next decreasing in diameter. Preferably the diameter and spacing of the apertures ranges between 250 nm and 2000 nm.

Preferably therefore the light in a second direction may be directed at any angle yet the focal point on the receiving means is suitably always over an aperture and therefore the conversion means beneath said aperture directly receives said light. Thus as light passes through the receiving means, at some point it encounters a cavity which resonates at its own wavelength.

In one embodiment, the apertures are triangular shaped. Preferably these triangular apertures are at least present in the surface material.

Optionally the apparatus may further comprise ground level reflectors. Preferably the ground level reflectors are positioned below the plurality of directing means upon the land on which the apparatus is located. Advantageously the ground level reflectors act to reflect any light energy not received in a first direction by the directing means, thereby causing a local geographic cooling effect around the apparatus. This local effect reduces the overall ambient temperature, and enhances the temperature difference between the starting temperature of the receiving portions and the heated temperature of the receiving portions after receiving light. An enhanced temperature difference means an increased mechanical stress on the conversion means and therefore an increased electrical energy output.

Optionally, the reverse of the directing means and the stand of the directing means may also comprise a mirrored surface with which to reflect any light energy not received in a first direction by the directing means.

Preferably the apparatus is controlled by the use of a computer program such that adjustment of the directing means, receiving means, cooling means, frequency of heating and cooling, positioning of the connectors, speed of rotation of the ring of conversion material forming the conversion means, sleeve and flow director is automated. Preferably the computer program parameters can be manually set and adjusted such that they are relevant to the particular apparatus and to the location of said apparatus, taking into account, for example: atmospheric temperature, pressure, wind speed and humidity, solar intensity and wavelengths. Preferably the computer program further comprises means for receiving data about the apparatus and components contained thereof, for example; temperatures of the receiving means, energy generation of the conversion means, power output etc. and warning signals indicating any problem with the apparatus. Preferably the computer program is remotely accessible and adjustable.

Preferably the ability of the connectors to predictively compensate for the expansion and contraction of the conversion material is provided as a function of the computer program.

Suitably the apparatus is arranged such that there is a field of directing means (as described above) at relative ground level, above which are located any number of receiving means each comprising at least two receiving portions, conversion means, and optionally a cooling means, which components are preferably arranged on a stand or suspended on wires. The stand or wires preferably support the receiving means, conversion means and optional cooling means at the optimal angle to the field of directing means to receive the light energy in the second direction. The portion of the stand or wires comprising said components of the apparatus may be termed a target. Meanwhile each of the directing means are optimally angled upon supports to receive light energy in the first direction from the light source, and redirect said light energy in a second direction onto a common focal point on the relevant receiving portion of the receiving means.

It is within the scope of the apparatus for any number of directing means and any number of receiving means to be present. Furthermore, it is within the scope of the apparatus for each receiving means to comprise any number of receiving portions.

In an alternative embodiment of the present invention, each receiving means preferably takes the form of a singular strip of substantially the same construction as described hereinabove. Preferably the receiving means are arranged side to side in vertical abutment such that the receiving means are arranged to form an overall cylindrical receiving drum, preferably such that the surface material of each receiving means faces outwards towards the field of directing means to receive light in a second direction.

Preferably each receiving means is arched in cross section such that the receiving drum becomes more cylindrical.

Preferably, the cylindrical receiving drum comprises between about 1 and 25000, more preferably between about 100 and 20000, still more preferably between 500 and 15000, most preferably 750 to 7500 receiving means.

Preferably, the number of heating and cooling zones comprises between about 1 and 5000, more preferably between about 20 and 5000, still more preferably between 100 and 3000, most preferably 150 to 1500 heating and cooling zones.

Preferably the receiving means are strips with a length of between about 5 and 20,000 metres, more preferably between about 8 and 5000 metres, still more preferably between about 15 and 900 metres, most preferably between about 25 to 400 metres, a width of between about 0.5 mm to 50 cm, more preferably between about 1 cm to 25 cm, still more preferably about 1.5 cm to 10 cm, most preferably about 1.75 cm to 5 cm, and a depth of between about 10 um and 0.003 um, more preferably 5 um and 0.05 um, still more preferably 3 um and 0.1 um, most preferably 1 um and 0.2 um.

Preferably the cylindrical receiving drum is located over a central core, preferably the core is also cylindrical and is preferably formed from a strong structural material such as concrete upon which the other components of the receiving means may be mounted securely.

Preferably an air cavity is disposed in a preferably annular arrangement around the central core, more preferably the air cavity is disposed in an annular arrangement between the central core and cylindrical receiving drum.

Preferably, in such an embodiment, the cooling means comprises a sleeve, wherein preferably the sleeve comprises a cylindrical drum which is operable to fit over the outside surface of the receiving drum. Preferably the sleeve is formed from a reflective material, such as, for example, a ceramic, silvered ceramic or polymeric material or a metallic material. Preferably the sleeve comprises a plurality of openings located therein, preferably the openings are rectangular shaped, suitably corresponding to the dimension of one receiving means.

Preferably the openings of the sleeve are located in a manner corresponding to the receiving means located beneath the sleeve. Preferably the openings broadly correspond to the receiving means, such that preferably half of the receiving means are exposed to light through the openings in the sleeve at any one time, and preferably half of the receiving means are covered by the sleeve at any one time.

Preferably the sleeve comprises a plurality of light shields, preferably the light shields are located between the openings of the sleeve and preferably act to substantially redirect light received in a second direction onto an exposed receiving means through an opening. Preferably therefore the light shields extend along at least the length of the openings and preferably comprise a triangular prism shape, more preferably a triangular prism with arcuate sides.

Preferably the light shields are held very close to the receiving means preferably using high accuracy actuators which preferably almost seal off the receiving means located beneath the light shields from the openings of the sleeve and further preferably comprise a heat retaining material and reflective material.

Preferably each light shield further comprises an air duct, preferably the air duct extends substantially through the centre of each light shield.

As the light in a second direction is received at the light shield, the light shield is heated and as a result the air present within the outer vicinity of the light shield is heated, as the air is heated it rises up the outer surface of the light shield to the top of the sleeve. Preferably the sleeve comprises a plurality of top and bottom vents positioned at substantially the top and bottom of each light shield. Suitably the air having risen up the outer surface of the light shield is captured by the top vents.

Preferably the cooling means further comprises a first fan, preferably positioned at the top of the sleeve. More preferably the first fan is positioned substantially over the air ducts of the light shields of the sleeve such that it is operable to drive air through the air ducts, more preferably from the top to the bottom of the air ducts. Preferably the first fan is a cylindrical fan suitably composing a plurality of vanes, said vanes preferably arranged in a ring formation substantially over the air ducts of the light shields of the sleeve.

Preferably the top vents of the sleeve open substantially onto the first fan such that air rising up the outer surface of the light shield is suitably drawn into the top vents and forced down the air ducts of the light shields. Suitably the air exits the air ducts at the bottom vents of the sleeve being recycled to again rise up the outer surface of the light shield.

Preferably the cooling means further comprises a second fan, preferably positioned at the top of the central core, air cavity, cylindrical receiving drum and sleeve arrangement. More preferably the second fan is positioned substantially over the air cavity, such that it is operable to drive air preferably from the bottom to the top of the air cavity. Preferably the second fan is also a cylindrical fan suitably composing a plurality of vanes, said vanes preferably arranged in a ring formation substantially over the air cavity.

Preferably the air cavity opens substantially onto the second fan such that air is suitably drawn from the atmosphere into the air cavity and forced up the air cavity. Suitably the air exits the air cavity at the top of the central core, air cavity, cylindrical receiving drum and sleeve arrangement.

Preferably the first and second fans are concentric with each other, more preferably the second fan is nested within the first fan.

Advantageously, the air movement through the air cavity and the air ducts acts to cool the receiving means when in the cooling phase of the oscillatory cycle. The cooling effect is achieved on a dual basis, the air movement through the air cavity cools the surface of the receiving means facing inwards towards the central core and air movement through the air ducts cools the light shields which in turn cools the surface material of those receiving means facing outwards towards the light shields.

Preferably the movement of air within the air cavity is arranged perpendicular to the airflow generated by rotation of the receiving means, thereby creating a tangential airflow of higher velocity and longer length across the the receiving means thus creating a greater cooling effect as a result.

Preferably the air cavity further comprises a plurality of enclosures, preferably the enclosures are positioned substantially beneath the receiving means when in the heating phase of an oscillatory cycle and substantially enclose each of those receiving means. Preferably the enclosures are held very close to the receiving means using high accuracy actuators which almost seal off those receiving means from the air cavity and preferably comprise a heat retaining material. The enclosures suitably act to insulate the receiving means in the heating phase from the cooling effect of the air cavity and to retain the heat generated by the light received in a second direction onto the receiving means. Preferably the enclosures comprise semi-circular tubes which preferably extend the length of each alternate receiving means, such that every other receiving means around the circumference of the receiving drum is located over an enclosure, and thereby with a hot zone.

The enclosures may be coated with a reflective material. The reflective material may be undulating, advantageously the radiated energy reflected therefrom may be directed back towards the receiving means beneath. Similarly, the air cavity and surrounding surfaces thereof may be coated with an absorption material to remove heat and prevent any increase in temperature.

Preferably the cylindrical receiving drum is operable to rotate around its major axis, preferably the cylindrical receiving drum rotates such that each receiving means is moved past the alternating light shields and openings present in the overlying sleeve, thereby creating an alternating pattern of heating phases and cooling phases over any receiving means. Preferably the cylindrical receiving drum is rotated through the heating and cooling zones at a frequency of heating and cooling of between about 2000 Hz and 0.5 Hz, more preferably between about 1300 Hz and 2 Hz, still more preferably between about 800 Hz and 12 Hz, most preferably between about 400 Hz to 25 Hz.

In a further alternative embodiment of the present invention, the receiving means may preferably comprise a plurality of pairs of receiving portions, each receiving portion preferably taking the form of a strip of substantially the same construction as described hereinabove.

In each pair of receiving portions, the first and second portions are preferably arranged end on such that they vertically abut, this arrangement suitably creates a first layer of receiving portions located above a second layer of receiving portions.

Preferably the pairs of receiving portions are arranged to form an overall cylindrical receiving drum as described hereinabove, preferably such that the surface material of each receiving portion faces outwards towards the field of directing means to receive light in a second direction.

Preferably the openings of the sleeve are located in two layers suitably corresponding to the first and second layers of the receiving portions located beneath the sleeve. Preferably the openings broadly correspond to every five receiving portions located in the first and second layers, such that preferably half of the receiving portions located in the first and second layers are exposed to light through the openings in the sleeve at any one time, and preferably half of the receiving portions located in the first and second layers are covered by the sleeve at any one time. Preferably the openings in the first layer of the sleeve are offset relative to the openings in the second layer of the sleeve, preferably the openings are offset by a distance broadly corresponding to the width of around 5 receiving portions. Accordingly, each receiving means at any point in time during use will preferably comprise a first receiving portion exposed to the light through an opening in the sleeve and a second receiving portion covered by the sleeve.

During any given point in the oscillatory cycle, for any receiving means, the first receiving portion positioned in the first layer of the receiving means is exposed via the openings in the sleeve and is heated, and simultaneously the second receiving portion positioned in the second layer of the receiving means is covered by the sleeve and is cooled, and vice versa.

Advantageously, in such an arrangement, the expansion or the contraction within any given receiving means is preferably offset because the first receiving portion is heated and second receiving portion is cooled, and vice versa. Therefore the contraction experienced in one receiving portion will be offset by the simultaneous expansion in the second receiving portion, and vice versa. In order for the expansion and contraction to be communicated between the first and second receiving portions, preferably the first and second receiving portions are connected via one or more connectors. Preferably the one or each connector is formed from a heat insulating material to substantially stop the transfer of heat between the first receiving portion which is heated, and the second receiving portion which is cooled. Preferably the connection material comprises a low Lorentz number, and may be selected from, for example: composites, carbon nanotubes, poly(3,4-ethylenedioxythiophene), poly(styrenesulfonate) and/or polyvinyl acetate.

Optionally, the conversion material within the receiving means is polarised horizontally such that the direction of polarisation extends laterally across each of the strips forming the first and second receiving portions. Preferably the first receiving portion is polarised in an opposite direction to the second receiving portion. Thus while the first receiving portion is being heated and the second receiving portion cooled, the generated electricity will flow in the same direction, and vice versa. Preferably therefore the sides of each receiving portion are electrically conductive. Preferably therefore the or each connector is also an electrical insulator.

Alternatively, the conversion material within the receiving means is polarised vertically such that the direction of polarisation extends longitudinally across each of the strips forming the first and second receiving portions. Preferably the first receiving portion is polarised in an opposite direction to the second receiving portion. Thus while the first receiving portion is being heated and the second receiving portion cooled, the generated electricity will flow in the same direction, and vice versa. Preferably therefore the ends of each receiving portion are electrically conductive. Preferably therefore the or each connector material is an electrical conductor.

Preferably the first and second receiving portions comprise one or more moveable anchor points to suitably tether the first and second receiving portions at either or both ends. The moveable anchor points may comprise one or more springs or actuators, preferably piezoelectric or electromagnetic actuators. Preferably the springs/actuators are tuned to the resonant frequency or a multiple thereof of the receiving means, more preferably to the resonant frequency or a multiple thereof of the conversion material of the receiving means. Optionally the or each connector may also be used to tune the springs/actuators to the resonant frequency thereof.

Preferably the cylindrical receiving drum is operable to rotate around its major axis, preferably the cylindrical receiving drum rotates such that the first and second receiving portions of each receiving means are moved past the alternating light shields and openings present in the overlying sleeve, thereby creating an alternating pattern of heating phases and cooling phases over any receiving portion. Preferably the cylindrical receiving drum is rotated through the heating and cooling zones at a frequency of heating and cooling of between about 2000 Hz and 0.5 Hz, more preferably between about 1300 Hz and 2 Hz, still more preferably between about 800 Hz and 12 Hz, most preferably between about 400 Hz to 25 Hz.

Advantageously, the present apparatus increases the commercially viability of using light energy to produce electrical energy for the mass market by decreasing the number of, and complexity of, components typically required to assemble such apparatuses, and by decreasing the number of energy transfers or conversions where potential energy losses occur.

According to a second aspect of the present invention, there is provided an apparatus for generating electrical energy from light energy, the apparatus comprising:
a plurality of directing means, wherein each directing means is configured to receive light energy in a first direction and redirect said light energy in a second direction;
receiving means configured to receive light energy in a second direction from each of the directing means, wherein the receiving means comprises at least two receiving portions, the receiving portions being arranged to alternately receive the light energy in a second direction from each of the directing means;
cooling means configured to cool the receiving means, wherein the cooling means alternately cools the receiving portions of the receiving means in antiphase to the light energy received by the receiving portions; and
conversion means configured to convert the light energy received by the receiving means into electrical energy.

Advantageously, the present apparatus increases the temperature change of the receiving means by cooling the receiving portion of the receiving means which is not receiving light from the second direction, such that each receiving portion is alternately heated by the light, and then cooled by the cooling means. Accordingly, the present apparatus optimises the output of the receiving means by creating a change in temperature on the heating interval and the cooling interval, and therefore twice the output of electricity for each alternation.

According to a third aspect of the present invention there is provided a method of generating electrical energy from light energy using the apparatus as defined in a first aspect of the present invention.

According to a fourth aspect of the present invention there is provided a method of generating electrical energy from light energy using the apparatus as defined in a second aspect of the present invention.

As used herein, the following terms can be regarded as having the definitions prescribed below:

The phrase ‘light energy’ as used herein can be defined as any radiant energy which is carried by a wave of photons in a transmitting material, specifically including wavelengths in the optical, ultraviolet, and infrared spectra.

The phrase ‘in a first direction’ as used herein in relation to light energy refers to the direction in which light energy travels from a light source onto each of the individual directing means in the field, the direction being specific to allow that individual directing means to receive light energy from the source. Nevertheless, in general, the plurality of directing means are in close proximity to each other so that the first direction need not differ significantly from one directing means to another, for example, less than 0.001°.

The phrase ‘in a second direction’ as used herein in relation to light energy refers to the direction in which light energy travels from a single directing means in the field onto a receiving means of the apparatus, the direction being specific to allow that individual directing means to focus light energy onto a receiving means in common with the other directing means.

The phrase ‘electrical energy’ as used herein can be defined as any potential energy which is carried by a current of charged particles in a conductive material.

The phrase ‘to directly convert’ as used herein in relation to energy can be defined as transformation between different energy types without any further component being necessary to the apparatus.

The word ‘alternately’ as used herein in relation to the receiving means can be defined as the light energy in a second direction being at one point in time directed towards a first portion of the receiving means, and being at another point in time directed towards a second portion of the receiving means such that the light energy in a second direction oscillates between the at least two receiving portions in a cycle.

The phrase ‘in antiphase’ as used herein in relation to the cooling means can be defined as the cooling means being at one point in time directed towards a first portion of the receiving means, and being at another point in time directed towards a second portion of the receiving means such that the cooling oscillates between the at least two receiving portions in a cycle, said cycle being phase shifted by half a wavelength relative to the oscillation of the light energy in a second direction described above.

The phrases ‘first receiving portion’ and ‘second receiving portion’ are intended to denote either of the receiving portions, which receiving portion referred to at any one time being interchangeable for the other.

The phrase ‘conversion material’ as used herein in relation to the conversion means is intended to include any material, including piezoelectric or pyroelectric material, which may or may not be present in a crystal form, that is capable of converting light energy into electrical energy and which forms the conversion means.

The phrase ‘preferably’ as used herein in relation to a further feature of the invention means ‘preferably herein the following feature applies to any aspect of the claimed invention’ and is not limited to being a feature of the aspect under which it is stated.

All of the features contained herein may be combined with any of the above aspects and in any combination.

For a better understanding of the invention, and to show how embodiments of the same may be carried into effect, reference will now be made, by way of example, to the accompanying diagrammatic drawings and examples in which:

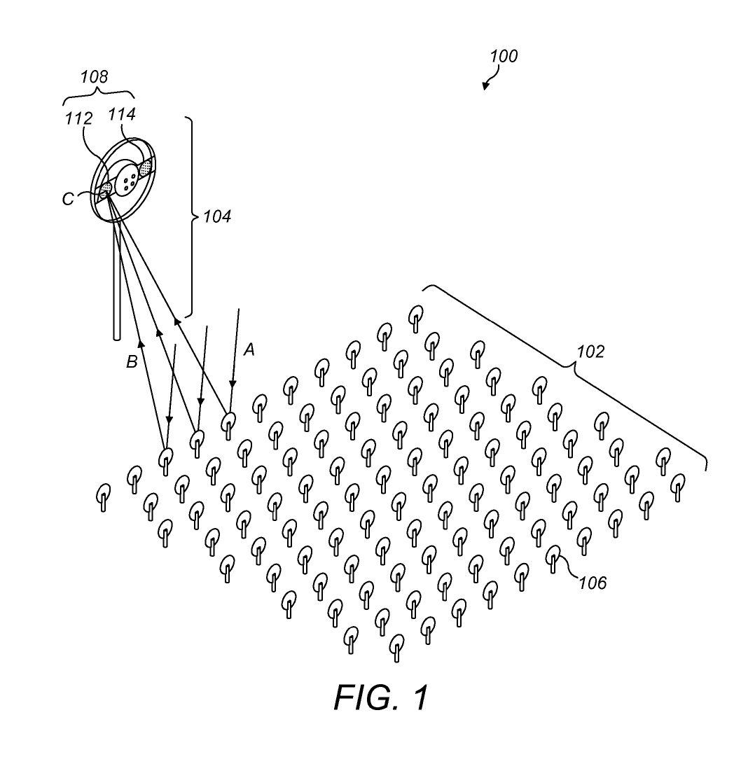

FIG. 1 shows a perspective view of one embodiment of the present invention.

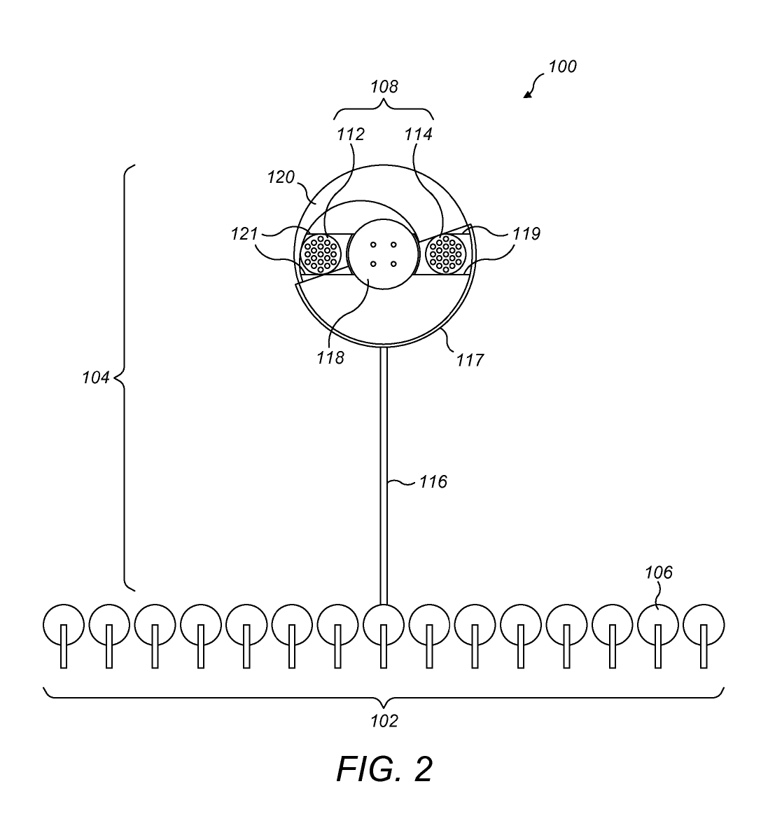

FIG. 2 shows a front view of one embodiment of the present invention.

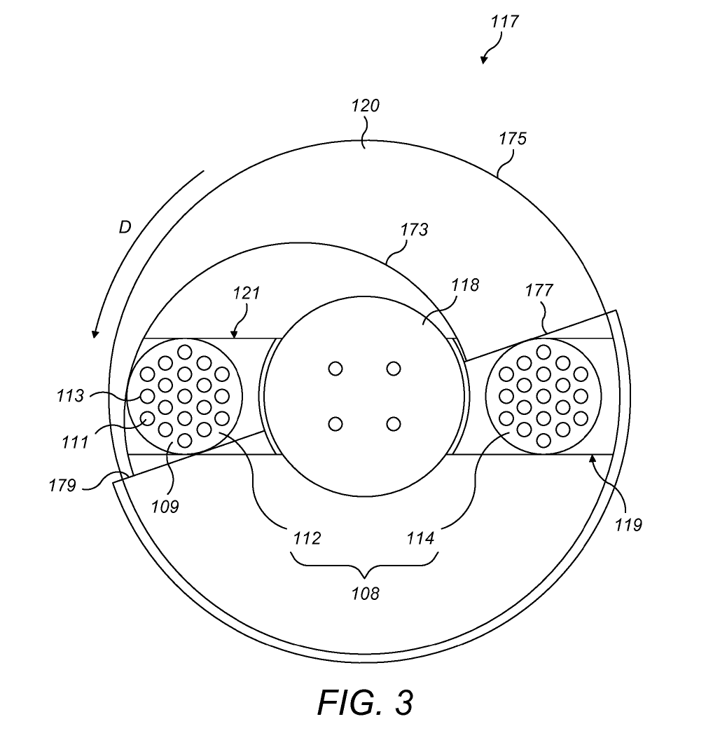

FIG. 3 shows a front view of one embodiment of a target of the present invention.

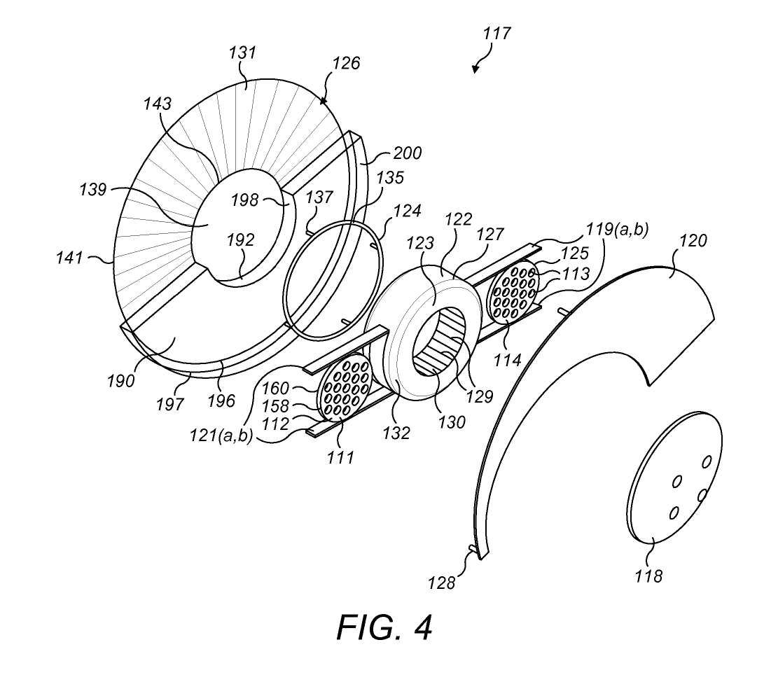

FIG. 4 shows an exploded perspective view of one embodiment of a target of the present invention.

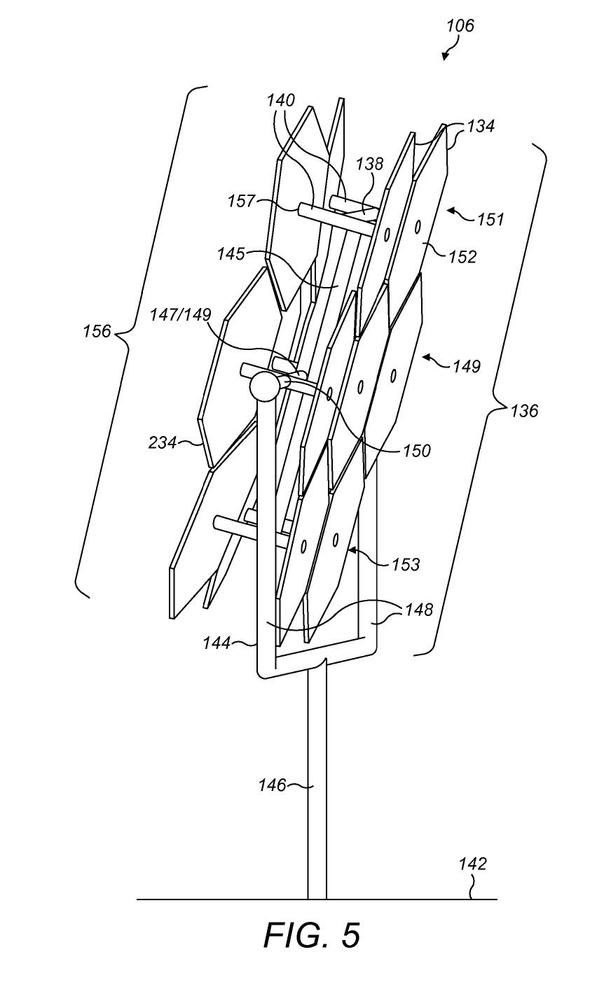

FIG. 5 shows a perspective view of one embodiment of the directing means of the present invention.

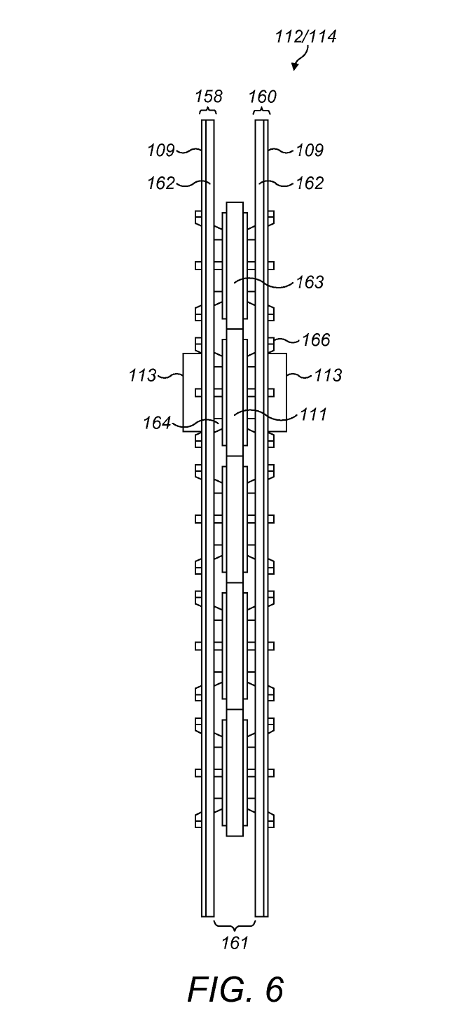

FIG. 6 shows a side view of one embodiment of the receiving means of the present invention.

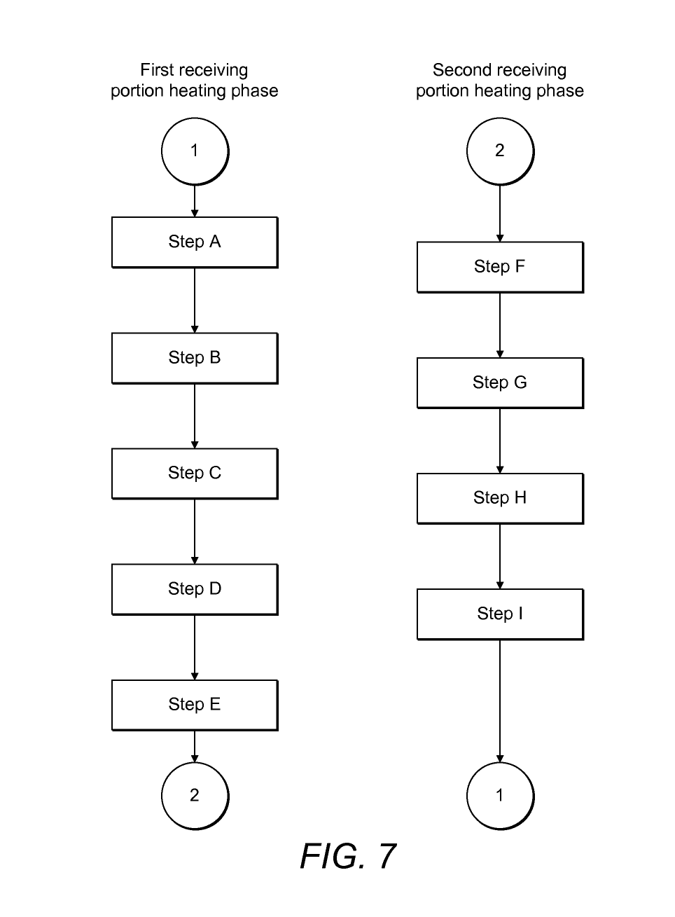

FIG. 7 shows a flowchart of the operation of one embodiment of the present invention.

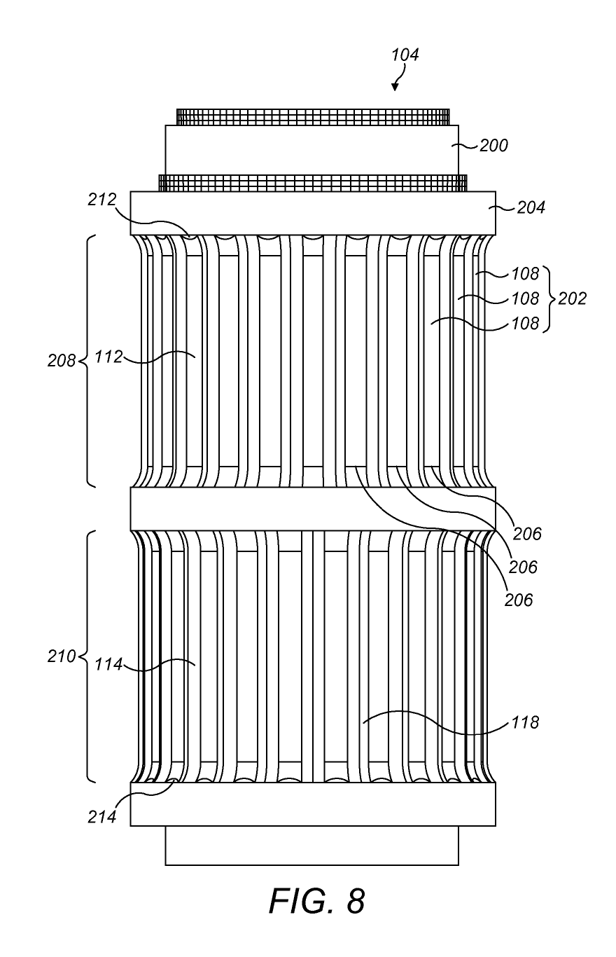

FIG. 8 shows a side view of a further embodiment of a target of the present invention.

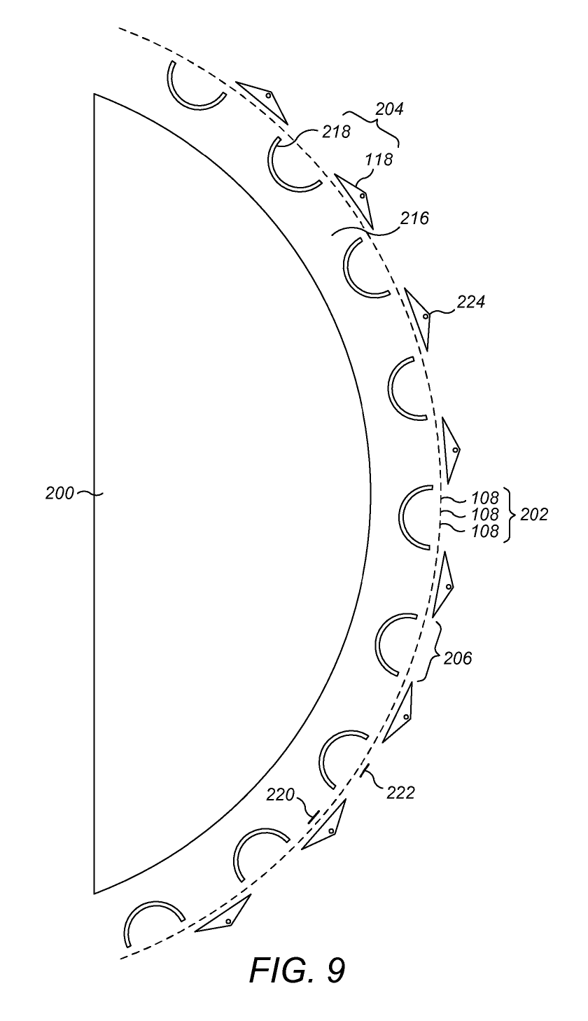

FIG. 9 shows a cross sectional view of a part of the target of FIG. 8.

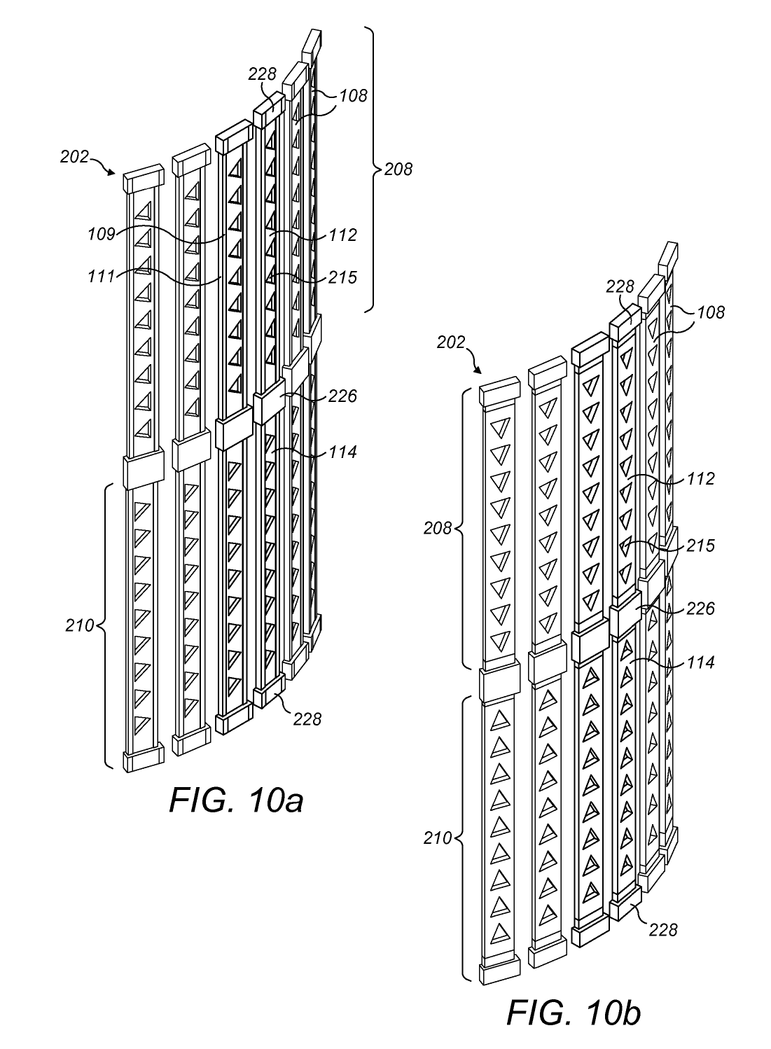

FIGS. 10a and 10b show perspective views of two alternative further embodiments of the receiving means of the present invention.

Example 1 is a theoretical working example of use of one embodiment of an apparatus of the present invention.

Referring to FIG. 1, the apparatus (100) comprises a field (102) and a stand (104), the field (102) generally comprising a plurality of directing means (106) and the stand (104) generally comprising receiving means (108), conversion means (not visible), and cooling means (not visible). The receiving means (108) comprising a first receiving portion (112) and a second receiving portion (114). The plurality of directing means (106) face towards the stand (104) in order to receive light individually in a first direction (shown by arrows A) from a light source (not shown), and reflect said light individually in a second direction (shown by arrows B) towards the receiving means (108). Each of the plurality of directing means (106) acts to redirect second direction light (B) onto a common focal point (C) at the centre of either the first or second receiving portions (112,114) of the receiving means (108) at any one time. Each of the directing means (106) is operable to adjust the angle of reflection and refocus, such that the light in a second direction (B) can be focussed upon the centre of the either of the receiving portions (112, 114). In this way, light in a second direction (B) can oscillate between being focussed on the first and second receiving portions (112, 114) at any one time.

Referring to FIG. 2, the stand (104) is shown in greater detail, and comprises an elongate support (116) extending above the field (102), and a target (117) at the distal end of the support which holds the receiving means (108), the cooling means (not visible), the conversion means (not shown), a light shield (118) and a sleeve (120). The light shield (118) covers the centre of the target (117), behind which is positioned the cooling means (not shown), which light shield (118) acts to disperse any light not received by the receiving means (108) back into the field (102) of directing means (106). Projecting from either side of the cooling means (not shown) are arm members (119,121), the arm members (119,121) being respectively adapted to support each of the receiving portions (114, 112) of the receiving means (108). The sleeve (120) acts to help direct the cooling air from the cooling means (not shown) onto alternate receiving means. In the present embodiment shown, the sleeve (120) is entering the shading phase of the first (112) receiving portion which is being cooled, whilst leaving the second receiving portion (114) exposed to the light.

Referring to FIG. 3, the sleeve (120) is operable to rotate around the target (117) in the direction of arrow D. In the embodiment shown, the target (117) is around halfway through one cycle of rotation. At this position, a first arm (121) of the target (117) comprising the first receiving portion (112) has just entered the cooling phase, and a second arm (119) of the target comprising the second receiving portion (114) has just entered the heating phase. The sleeve (120) is generally semi-circular and has an outer circumferential edge of the same diameter and concentric with the outer edge of the target (117) along its entire length whereas the inner edge (173) of the sleeve has a diameter about two-thirds that of the outer edge (175) and is additionally centred in an offset manner so that the sleeve tapers from a wider end (177) which fully covers a receiving portion to a narrower end (179) which does not shade any part of a receiving portion. As the sleeve (120) rotates, the first receiving portion (112) is gradually covered until it is fully shaded by the sleeve (120). During rotation, the sleeve (120) is directing cooling air from the cooling means (not shown) across the first receiving portion (112), with maximal cooling taking place when the sleeve (120) fully covers the first receiving portion (112). Meanwhile, cooling air from the cooling means (not shown) is blocked from the second receiving portion (114), and the second receiving portion (114) is fully exposed to the light in the second direction, which is being directed at the second receiving portion (114) by the directing means (not shown). The sleeve (120) continually rotates at a rate which is equivalent to the rate of oscillation of the light in the second direction between the receiving portions (108), such that the sleeve (120) has just passed and uncovered a receiving portion (112 or 114) when the light is directed onto it. Similarly, the sleeve continually rotates in phase with the oscillation of the cooling means, such that whenever the cooling means (not shown) is directing air across either the first or second receiving portion (112,114), the sleeve (120) is also covering that same first or second receiving portion (112, 114) being cooled.

Also visible in this figure are some details of the receiving means (108), the surface material (109) covers the outwardly facing portion of the receiving means (108) which is configured to receive the light in a second direction from the directing means (106). Below the surface material (109) are mounted a series of piezoelectric/pyroelectric elements (111) seen through apertures (113).

Referring now to FIG. 4, all of the components of an embodiment of the target (117) can be seen. In order from front to back, the light shield (118) is positioned at the centre of the target (117) circumferentially disposed around the light shield (118) is located the sleeve (120). The sleeve (120) comprising a plurality of sleeve actuators (128) outwardly protruding therefrom towards the rear of the target (117).

Positioned directly behind the light shield (118) is located the cooling means (122). The cooling means (122) comprises a ring (123) having radial inner and outer peripheral surfaces (125, 127), a plurality of circumferentially spaced radially inwardly extending vanes (129) formed on the inner peripheral surface (125) forming the basis of a centrifugal fan (130). The outer surface (127) is plain and the cooling means (122) includes a close fitting cowling (132) extending circumferentially around the outer peripheral surface (127). A pair of aligned arm members (119, 121) extend outwardly from opposite sides of the ring (123). Each arm member (119,121) comprises a pair of parallel spaced arms (119a,119b,121a,121b) which secure a disc shaped receiving portion (112,114) therebetween. The disc shaped receiving portions (112, 114) together form the receiving means (108) and are orientated in the same plane as the ring (123) of the cooling means (122) and each comprise a first surface (158), a second surface (160) spaced from and aligned therewith, and brackets (not shown) securing piezoelectric/pyroelectric elements (111) therebetween. The first surface (158) is located on the side of the receiving portion (112, 114) which receives light in a second direction (B) and includes an array of apertures (113) formed therein. Beneath the apertures (113) are shown the piezoelectric/pyroelectric elements (111).

Positioned directly behind the cooling means (122) is located a vent (124) circumferentially disposed around the cowling (132) of the cooling means (122) and operable to rotate around a periphery thereof. The vent comprising a slotted hoop (135) (slots not visible) with a plurality of actuators (137) extending outwardly therefrom towards the rear of the target (117).

Positioned at the rear of the target (117) is a sheath (126) comprising a ring shaped base plate (131) with a central aperture (139). The base plate has located over its lower half an arcuate fixing/guide plate (190) having an inner edge (192) aligned with and of the same radius as the inner edge (143) of the base plate (131) and an outer edge (194) that slightly overlaps the outer circumferential edge (196) of the base plate (131). The inner and outer edges of the guide plate (190) that are contiguous with the inner and outer edges of the baseplate have forwardly directing guide rims (198,200) extending perpendicularly therefrom.

In assembly, the outer circumferential edge (141) of the sheath (126) is slideably connected to the actuators (128) of the sleeve (120) such that the sleeve (120) is held away from the base plate (131) of the sheath (126) by enough distance such that the sleeve (120) may rotate circumferentially around the cooling means (122) in a plane above the surface (158) of the receiving means (108) and arm members (119,121). The distance that the sleeve (120) is held at may be altered by extending or retracting the actuators (128). Furthermore, the inner guide rim (198) of the sheath (126) is slideably connected to the actuators (137) of the vent (124) such that the vent (124) may also rotate circumferentially around the periphery of the cooling means (122).

The lightshield (118) is attached to the front of the ring (123) of the cooling means (122), the back of the ring (132) of the cooling means (122) is positioned within the hoop (135) of the vent (124), the vent (124) is slideably connected to the sheath (126) as described above, the cooling means (122) sits within the central aperture (139) of the sheath (126) and is attached thereto, such that the first and second arm members (119,121) lie substantially against the base plate (131) and such that the vent (124) overlaps the periphery of the back of the ring (132) of the cooling means (122).

In operation all components of the target 117 are secured together apart from the sleeve (120) and the vent (124) which may rotate in the same direction around the central cooling means (122) at the same rate. When rotating, the slots in the hoop (135) of the vent (124) act to direct the air flow of the fan (130) across the surface (158) of either of the first or second receiving portions (112, 114) to be cooled. The vent (124) is operable to rotate with the sleeve (120) such that the cooling air of the fan (130) is directed onto the same receiving portion (112, 114) as that being covered by the sleeve (120).

Referring now to FIG. 5, the directing means (106) comprises a plurality of light reflectors (134) arranged to form a first reflector array (136) having a facing surface and a rear surface and a plurality of reflectors (234) arranged to form a second generally parallel reflector array (156) having a facing surface and a rear surface. The second reflector array (156) is spaced from and generally parallel to the first reflector array (136) and arranged so that the light facing surface thereof faces in the opposite direction to the first reflector array light facing surface. Each light reflector (134, 234) is secured to a reflector support (138) disposed between the first and second reflector arrays (134, 234).

The reflector support (138) comprises a series of supporting members (140) fixed at one end to and extending outwardly from a grid arrangement comprising longitudinal bars (145) and horizontal bars (147) which are approximately equally spaced from and generally parallel with the reflector arrays (136, 156). Each supporting member (140) is connected at its opposite end to the centre of the reverse side (157) of one of the plurality of reflectors (134, 234), and is adjustable by means of a ball and socket joint (not visible) such that each reflector (134, 234) may be rotated in any axis.

The reflector support (138) is pivotably mounted in a ‘U’-shaped frame member (144) which is itself mounted on an upper end of upright elongate cylindrical member (146) extending from the base (142) in which it is journalled for rotation about its axis to the base of the ‘U’-shaped member. The two side arms (148) of the ‘U’-shaped member (144) which extend upwardly from the base thereof each have an axle (150) extending perpendicular to the side arms (148) and journalled in the upper ends thereof. In this manner, the reflector support (138) is capable of rotating in the x axis around the axle (150), and the entire directing means (106) is capable of rotating in the y axis around the axis of the elongate member (146). The reflector support (138) is also capable of adjustment in the axial direction of the cylindrical member (146) by raising or lowering the cylindrical member (146).

The reflectors (134,234) are in the form of hexagonal plates which tessellate to form the facing surfaces (136, 156), shown in FIG. 5 as a collection of three reflectors on a central row (149), with a top row (151) and a bottom row (153) of two reflectors disposed above and below but in the same plane as the central row (149) thereof. The plates (134, 234) comprise a mirrored upper surface (152) so as to receive light in a first direction (A) and redirect said light in a second direction (B). Each of the reflectors (134,234) may be angled such that the entire facing surfaces (136,156) form a cohesive shape, such as a concave dish as shown. The concave shape allows the reflectors (134,234) to focus the light in the second direction (B) onto a common focal point on the receiving means (not shown).

In the present embodiment shown, the directing means (106) comprise a further second facing surface (156) essentially identical to the first facing surface (136) apart from a difference in focal distance of the reflectors. The second facing surface (156) is positioned such that it faces in the opposite direction to the first facing surface (136) so as to reflect light in the opposite direction to the first facing surface (136). The reflectors (234) of the second facing surface (136) are supported by the same supporting members (140) as the reflectors of the first facing surface (136) by the supporting members (140) extending outwardly in both a forward and a reverse direction from the grid arrangement, such that a single supporting member (140) has a reflector (134, 234) mounted at either end thereof. The supporting members (140) space the second facing surface (156) and first facing surface (136) from the longitudinal and horizontal bars (145,147) of the central reflector support (138) disposed therebetween.

Referring now to FIG. 6, one of the disc shaped receiving portions (112,114) of the receiving means (108) is shown comprising a first plate (158) and an aligned parallel second plate (160), spaced from the first plate. The exterior facing surface material (109) of each of the plates consists of a thin layer of conductive material such as graphene and the interior facing side consists of an insulating material (162), typically mica. Each of the first and second plates (158,160) has formed therein a plurality of spaced circular apertures (113), aligned with mutually opposed apertures (113) on the opposing plate (160). A plurality of piezoelectric/pyroelectric disc shaped elements (111) is sandwiched between the plates (158, 160) in the gap (161). The elements are suspended in place within the gap (161) by a plurality of brackets (164) extending from the plates to the elements (111). The brackets (164) contact the elements (111) at three points around the edge of the elements (111) and are usually manufactured from layered mica to insulate the elements (111) and impede any heat transfer. Beneath the exterior facing surface material (109) of each of the plates (158, 160) and connected to the brackets (164) is a sprung steel or titanium frame (not shown) which provides tension to the receiving means (108) and allows for expansion of the elements (111) under heat. The layered arrangement of the receiving portions (112,114) allows the most efficient localisation of heat from the surface material (109) around the piezoelectric/pyroelectric elements (111) during a heating phase, whilst also allowing cooling air to circulate through the receiving means and around the maximal surface area of the piezoelectric/pyroelectric elements (111) during a cooling phase.

Referring now to FIG. 7, there is shown a simplistic flowchart detailing the general operation of one embodiment of the present invention over time. On the left hand side is shown the sequence of events for the first receiving portion (112), and on the right hand side is shown the parallel and simultaneous sequence of events for the second receiving portion (114). The sequence of events for each receiving portion (112,114) occurring in the order as shown and as indicted by the arrows between each event as shown in the boxes and explained below. It is to be understood that once the sequence of events for one of the receiving portions (112 or 114) is completed, the other sequence of events will then take place, such that, for example, the first receiving portion becomes the second receiving portion and vice versa in a continuously alternating manner.

The sequence of events for the first receiving portion (112) is shown on the left hand side of the figure, which in the present example is in the heating phase. The heating phase begins with step A and ends at step E. Steps A to E are as follows:

Step A: The sleeve rotates such that the first receiving portion is exposed to receive light.

Step B: The directing means move to redirect light in the second direction onto the first receiving portion. Air from the cooling means is blocked from the first receiving portion by the hoop of the vent, the vent being rotated together with the sleeve.

Step C: Light in the second direction is focused and concentrated on the exterior facing surface material of the first receiving portion.

Step D: The temperature of the first receiving portion rises, which heat is localised around the conversion means and electricity is generated via the pyroelectric effect or via the piezoelectric effect.

Step E: A set time interval elapses and the heating phase completes, the first receiving portion now becomes the second receiving portion.

Simultaneously, the sequence of events for the second receiving portion (114) is shown on the right hand side of the figure, which in the present example is in the cooling phase. The cooling phase begins with step F and ends at step I. Steps F to I are as follows:

Step F: The sleeve and the vent rotate such that second receiving portion is covered and the slots in the hoop of the vent are aligned with the second receiving portion forming a shaft for airflow.

Step G: The directing means move to redirect light away from the second receiving portion. Air from the cooling means is directed via the slots in the hoop of the vent across the surface of the second receiving portion beneath the sleeve.

Step H: The temperature of the second receiving portion falls, which cooling is localised around the conversion means and electricity is generated via the pyroelectric effect or via the piezoelectric effect.

Step I: A set time interval elapses and the cooling phase completes, the second receiving portion now becomes the first receiving portion.

Referring to FIG. 8, there is provided a stand (104), the stand (104) generally comprising a central cylindrical core (200) formed from concrete, a plurality of receiving means (108) comprising strips of conversion material arranged side by side in vertical abutment to form a cylindrical receiving drum (202), and a cylindrical sleeve (204). The cylindrical receiving drum (202) is arranged around the annular of the core (200) and the sleeve (204) is arranged around the annular of the cylindrical receiving drum (202) in a triple layered cylinder. The core (200) is annularly displaced from the cylindrical receiving drum (202) to create an air cavity (not shown) between the two cylinders. Each of the receiving means (108) comprises a first receiving portion (112) and a second receiving portion (114), the first receiving portions (112) disposed in a first top layer (208) of the sleeve (204) and the second receiving portions (114) disposed in a second bottom layer (210) of the sleeve. The sleeve (204) comprises a plurality of openings (206) which allow the receiving portions (112,114) to be exposed to the light in a second direction, and a plurality of light shields (118) which cover the receiving portions (112,114) and shade them from the light. The openings (206) and the light shields (118) are substantially the same size and equate to approximately five receiving portions (112,114). The openings (206) and the light shields (118) are distributed alternately in the surface of the sleeve (204). The first top layer (208) of the sleeve (204) is offset by one opening (206) relative to the second bottom layer (210) of the sleeve (204) such that any one receiving means (108) comprises a first receiving portion (112) exposed to the light through an opening (206) and a second receiving portion shaded from the light by a light shield (118). In use, the cylindrical receiving drum (202) rotates around the cylindrical core (200) such that each receiving portion (112,114) is moved alternately past the openings (206) in the sleeve (204) and the light shields (118) to create an alternating pattern of hot and cold zones in which the receiving portions (112,114) are exposed to the light and heated, or shaded from the light and cooled. The sleeve (204) allows only one of the first or second receiving portions (112,114) of each receiving means (108) to be exposed and heated at any one time, the other receiving portion (112,114) is covered by a lightshield (118) and cooled. The expansion of one receiving portion (112,114) is compensated for by the contraction of the other receiving portion (112,114) in each receiving means (108). This movement is communicated between receiving portions (112,114) by means of connectors (not shown) positioned at the centre of each receiving means (108) between the first and second receiving portions (112,114), the movement is also buffered by means of moveable anchors (not shown) formed from springs or actuators which are positioned at both longitudinal ends of the receiving means (108). The rotation of the cylindrical receiving drum (202) may be driven by a stepper motor (not shown) and the drum (202) is mounted on ball bearings or magnetic bearings to reduce friction during rotation. Each of the lightshields (118) further comprises an embedded air duct (not visible) located within the body of the lightshield which comprises a cylindrical tube or pipe suitable to transport air and cool the lightshields (118). The sleeve (204) further comprises top vents (212) and bottom vents (214) located at the top and bottom of each opening (206). The vents (212,214) are formed from apertures in the sleeve (204). The top vents (212) act to capture rising hot air from the surface of the receiving means (108). Immediately behind the top vents (212) is located a first axial fan (not shown) comprising a ring of vanes, the first fan being located at the top of the stand (104) within the sleeve (204) and the vanes being located over the air ducts (not visible) of the lightshields (118). In use, the fan (not shown) draws hot air in from the top vents (212) and expels the hot air down the air ducts (not visible) within the light shields (118) of the sleeve (204). This air acts to cool the inside of the light shields (118). The air is then expelled from the bottom vents (214) of the sleeve (204) being recycled to again rise up the outer surface of the light shields (118). A second axial fan (not visible) is also located at the top of the stand (104) nested within, and concentric to, the first fan (not shown). The second fan (not visible) comprises a ring of vanes (not shown), the vanes positioned over the air cavity (not shown). In use, the second fan (not visible) draws cool air in from the atmosphere and expels it through the air cavity (not visible) from the bottom of the stand (104) to the top. This air acts to cool the exposed inside surface (not visible) of the receiving portions (112,114) that are located in a cool zone beneath a lightshield (118). The air is then expelled from the top of the air cavity (not visible) at the top of the stand (104) to the atmosphere.

Referring now to FIG. 9, the stand (104) of FIG. 8 is shown in a partial cross section wherein, starting from the innermost cylinder and moving radially outwards the cylindrical core (200), the air cavity (216), the cylindrical receiving drum (202) and the sleeve (204) are shown in successive annular rings. The cylindrical receiving drum (202) comprises a plurality of receiving means (108) each comprising a vertical strip arranged side by side to form a cylinder, the receiving means comprising an inside surface (220) facing the core (200) and an outside surface (222) facing the atmosphere. The sleeve (204) comprises a plurality of openings (206) through which the receiving means (108) are exposed, and a plurality of light shields (118) beneath which the receiving means (108) are covered. The sleeve (204) further comprises a plurality of enclosures (218) comprising a semi-circular cross section and extending the length of the receiving means (108). The enclosures (218) are positioned behind the inside surface (220) of the receiving means (108) and aligned with the openings (206) of the sleeve (204) and comprise a heat insulating material. The enclosures (218) act to retain the heat around the receiving means (108) when in a hot zone of the oscillatory cycle. The lightshields (118) comprise a triangular cross section and also extend half the length of the receiving means (108) i.e. the length of a receiving portion (112,114). The light shields (118) are positioned over the outside surface (222) of the receiving means (108) alternately to the enclosures (218) and openings (206). The receiving means (108) beneath the light shields (118) are shaded from the light and the inside surfaces (220) are exposed to the air cavity (216) to optimise cooling. Each of the light shields (118) further comprises an air duct (224) comprising a cylindrical tube which extends the length of the lightshield (118) and which allows air to circulate through the lightshield (118) from the top vents to the bottom vents of the sleeve (204), this air being driven by the first fan (not shown) Air is also circulated from the bottom to the top of the stand (104) via the air cavity (216) which allows the inside surface (220) of the receiving means (108) to be cooled, this air being driven by the second fan. In use, the cylindrical receiving drum (202) rotates such that the receiving means (108) are moved through alternate hot zones created by the enclosures (218) and the openings (206), and cold zones created by the air cavity (216) and the lightshields (118).

Referring to FIGS. 10a and 10b, a close up perspective view of two alternative embodiments of the receiving means in the cylindrical receiving drum of FIGS. 8 and 9 are shown. Each of the receiving means (108) comprising a first receiving portion (112) and a second receiving portion (114) which together form a strip comprising a surface material (109) which covers the outwardly facing portion of the receiving means (108) and conversion means formed from piezoelectric/pyroelectric material (111) located beneath the surface material (109). The first receiving portion (112) positioned on the first top layer (208) of the cylindrical receiving drum (202), and the second receiving portion (114) on the second bottom layer of the cylindrical receiving drum (202). The first and second receiving portions (112,114) are connected by connectors (226) positioned between the two receiving portions (112,114) at the centre of the receiving means (108). At the top end of the first receiving portion (112) and at the bottom end of the second receiving portion (114) are moveable anchors (228) formed from springs which act to elastically connect the receiving means (108) to the core (not shown). The piezoelectric/pyroelectric material (111) may be polarised in one of two directions. In FIG. 10a, the piezoelectric/pyroelectric material (111) is polarised horizontally from one side of the receiving means (108) to the other, and the receiving portions (112,114) further comprise triangular apertures (215) orientated to point with the direction of polarisation. In FIG. 10b, the piezoelectric/pyroelectric material (111) is polarised vertically from one end of the receiving means 108 to the other, and the receiving portions (112,114) further comprise triangular apertures (215) orientated to point with the direction of polarisation. In each case, the first receiving portion (112) is polarised in an opposite direction to the second receiving portion (114). Therefore, in FIG. 10a, the first receiving portion (112) is polarised from right to left, whilst the second receiving portion (114) is polarised left to right. In FIG. 10b, the first receiving portion (112) is polarised from top to bottom and the second receiving portion (114) is polarised from bottom to top. Thus, in use, while the first receiving portion (112) is being heated and the second receiving portion (114) cooled, the generated electricity will flow in the same direction, and vice versa. Therefore, in FIG. 10a, the connectors (226) may be formed from an electrically insulating material since electricity is conducted from the receiving means (108) at either side of the receiving portions (112,114). In FIG. 10b, the connectors are formed from electrically conductive material since electricity is conducted from the receiving means (108) at the top and bottom of the receiving means (108).

### EXAMPLE 1

### Theoretical Example of Use of an Apparatus of the Present Invention

### Receiving Means Dimensions

The surface of each of the receiving means for receiving solar radiation consists of 11,520 rectangular Lithium Tantalate crystals that also act as conversion means. The individual crystals having dimensions of 100 millimetres length by 1 millimetres width, and being arranged circumferentially in a ring of diameter 3.667 metres such that the crystals are held at their ends and extend outwardly from the centre of the ring.

The ring of crystals is rotated at a speed of 56720 rpm or 945.333 Hz.

Solar radiation is directed at the ring at 12 evenly spaced heating zones, these heating zones are interspersed with 12 evenly spaced cooling zones. The heating and cooling zones being of equal width.

Thus each crystal undergoes heating and cooling 12 times per rotation of the ring. The frequency per cycle of heating and cooling is therefore 11,344 Hz.

### Mechanical Resonance

Lithium tantalate has a bulk modulus of 9.6 gigapascals and a density of 7460 Kilograms per metres cubed, thus the velocity of sound through the crystal is 1134 metres per second (Given by square root of the bulk modulus divided by the density).

The fundamental resonant frequency of the crystals (in longitudinal mode) is then 5672 Hz (Given by the velocity of sound through the crystal divided by twice the length).

In this example the frequency of heating and cooling is therefore twice that of the resonant frequency, and the crystals will oscillate at twice their fundamental frequency or at the 1st harmonic.

Thus the crystals will be resonating at this frequency. Experimental data (Glass and Abrams 1970, reproduced in “Principles and Applications of Ferroelectrics and Related Materials” M. E. Lines and A. M. Glass, Thermodynamic Properties 5.1) shows the effect of resonance is to increase the output voltage by up to 16 times.

### Specific Heat of Each Crystal

Each crystal is made up of a first layer of graphene, Lithium tantalate crystal, a second layer of graphene and a layer of carbon nanotubes for light absorption.

The lithium tantalate layer is 3.3 nanometers thick. Thus the volume of each crystal is 0.000327 cubic nanometers.

The density of Lithium Tantalate is 7460 Kilograms per metre cubed, and the specific heat capacity is 420 joules per Kilogram kelvin. The total heat capacity of each crystal is then 0.000001025 joules per kelvin (Given by the volume multiplied by density multiplied by the specific heat capacity).

### Temperature Rise Per Crystal

The cycle time for the crystal to progress through one revolution of the hot and cold zones is 0.000088 seconds (Given by the reciprocal of the Period).

The hot zone time is then 0.000044 seconds (Half the hot and cold cycle time).

During the hot zone each crystal will pass through 12 watts of solar energy. This will give rise to a temperature increase of 500 Kelvin (Given by hot cycle time multiplied by the power in watts divided by the heat capacity).

### Field Dimension

For the surface described with 5760 crystals being heated at any one time, the field of directing means directing solar radiation towards the receiving means would need to be of a size of approximately 67.68 metres squared (Given by power per crystal contained in the conversion means times half the number of crystals times (approximately) 5 for spacing). As the system starts to resonate, an additional 67.68 metres squared would be required for the same temperature rise, as during this phase more of the heat is turned to electrical power.

### Cooling Phase

During the cooling zones a fan producing an airflow of 95 metres per second provides a cooling capability of approximately 12 watts per crystal, the cost of the acceleration of the air being 0.055203 watts.

### Energy Produced

Without resonance each crystal will produce voltage and current as follows: The rate of temperature rise is 11466349 Kelvin per second (500 Kelvin/0.000044 seconds).

The equation for voltage generation for a pyroelectric material is:

pyroelectric coefficient×crystal thickness×change in temperature per second/(dielectric permittivity×electric constant)
The pyroelectric coefficient for Lithium Tantalate is 0.0002 coulombs per metre squared Kelvin.
The crystal thickness is 3.3 nanometres
The change in temperature is 11466348.957 degrees per second.
The dielectric permittivity is 45 (ratio).
The electric constant is 8.85419×10 exp−12 coulombs per volt metre.

Thus this rate of temperature change will give rise to a rate of voltage rise of 18993.62 volts per second.

For the given hot zone time of 0.000044 seconds this will lead to a generated voltage of 0.828 volts (Given by the volts per second multiplied by the hot zone time).

The equation for maximum current for a pyroelectric material is:

area of the crystal×change in temperature per second×pyroelectric coefficient.

The area of one crystal is 0.000099 metres squared.

Thus the temperature change will give rise to a maximum current of 0.227282 amperes.

Thus the maximum electrical energy produced over all hot zones would be 0.094121 watts (Given by voltage times current divided by 2).

Thus the maximum electrical energy produced over all cold zones would be 0.038918 watts (Given by hot cycle minus the cost of the fan).

The total energy produced will therefore be 0.13304 watts.

The efficiency Without′ resonance will therefore be 1.132254%. Which efficiency is a significant increase on the current solar power systems available and should enable commercial solar power to become a viable option by use of the present apparatus.

### Resonance Effect on Energy Produced

As the crystal resonates the rate of voltage rise will increase by up to 16 times. The rate of current produced will also increase by up to 16 times. However each effect will level off as the electricity produced starts to subtract energy from the power heating the crystal. It is expected that this roll off will occur rapidly as the efficiency approaches 50%. In this example the speed of rotation will be modified such that the resonant voltage does not exceed 5.59 times the 0.828 volts generated in the heating zone.

### Peripheral Edge Region Required for the Voltage Gradient

The breakdown voltage of air is 3000 kilovolts per metre.

Under resonance, a 16 fold increase in the voltage will result in 13.252 volts. Thus a peripheral edge region of 0.004417333 millimetres will be sufficient between a central area and the edge of the crystals on all sides (Given by the resonant voltage divided by the breakdown voltage of air) to avoid shorting.

The heating of this peripheral edge region will result in a loss of efficiency of approximately 0.891557%.

The reader's attention is directed to all papers and documents which are filed concurrently with or previous to this specification in connection with this application and which are open to public inspection with this specification, and the contents of all such papers and documents are incorporated herein by reference.

All of the features disclosed in this specification (including any accompanying claims, abstract and drawings), and/or all of the steps of any method or process so disclosed, may be combined in any combination, except combinations where at least some of such features and/or steps are mutually exclusive.

Each feature disclosed in this specification (including any accompanying claims, abstract and drawings) may be replaced by alternative features serving the same, equivalent or similar purpose, unless expressly stated otherwise. Thus, unless expressly stated otherwise, each feature disclosed is one example only of a generic series of equivalent or similar features.

The invention is not restricted to the details of the foregoing embodiment(s). The invention extends to any novel one, or any novel combination, of the features disclosed in this specification (including any accompanying claims, abstract and drawings), or to any novel one, or any novel combination, of the steps of any method or process so disclosed.

1. An apparatus for generating electrical energy from light energy, the apparatus comprising:
a plurality of directing means, wherein each directing means is configured to receive light energy in a first direction and redirect said light energy in a second direction, wherein the light energy in the first direction is emitted from a light source;
receiving means configured to receive light energy in the second direction from each directing means; and
conversion means configured to directly convert the light energy received in the second direction into electrical energy.

2. The apparatus of claim 1, in which the directing means comprises one or more reflectors arranged to focus light energy to a focal point.

3. (canceled)

4. The apparatus of claim 2, in which the one or more reflectors present upon a single directing means are arranged to focus the light energy in a second direction to the same focal point on the receiving means.

5. (canceled)

6. The apparatus of claim 1, in which the receiving means comprises a surface material capable of receiving and absorbing light energy, and an insulating material.

7-11. (canceled)

12. The apparatus of claim 1, in which the receiving means comprises at least a first receiving portion and a second receiving portion.

13-14. (canceled)

15. The apparatus of claim 1, in which the conversion means is formed from piezoelectric or pyroelectric material.

16-18. (canceled)

19. The apparatus of claim 1, in which the conversion means is integral to the receiving means of the apparatus.

20. The apparatus of claim 19, in which the surface material overlays both sides of the conversion means such that a sandwich type arrangement is produced with a central conversion means surrounded by surface material.

21. The apparatus of claim 20, in which the conversion means is rotatable together with the receiving means.

22. The apparatus of claim 1, in which the conversion means is polarised horizontally such that the direction of polarisation extends laterally across each of the receiving portions.

23. (canceled)

24. The apparatus of claim 1, in which as the light energy in the second direction oscillates its point of focus between at least the first and second receiving portions, one of the receiving portions is receiving and absorbing the light energy and heating, whilst the other is not receiving any light energy and is cooling.

25. The apparatus of claim 1, in which the apparatus further comprises a cooling means.

26-29. (canceled)

30. The apparatus of claim 1, in which the conversion material forming the conversion means is alternately heated and cooled by movement of the conversion means together with the receiving means.

31. The apparatus of claim 30, in which the conversion material in the conversion means is arranged in at least one ring and the ring is operable to rotate.

32-41. (canceled)

42. The apparatus of claim 1, in which the receiving means are arranged side to side in vertical abutment such that the receiving means are arranged to form an overall cylindrical receiving drum.

43. The apparatus of claim 42, in which each receiving means is arched in cross section such that the receiving drum becomes more cylindrical.

44. (canceled)

45. An apparatus for generating electrical energy from light energy, the apparatus comprising:
a plurality of directing means, wherein each directing means is configured to receive light energy in a first direction and redirect said light energy in a second direction;
receiving means configured to receive light energy in a second direction from each of the directing means, wherein the receiving means comprises at least two receiving portions, the receiving portions being arranged to alternately receive the light energy in a second direction from each of the directing means;
cooling means configured to cool the receiving means, wherein the cooling means alternately cools the receiving portions of the receiving means in antiphase to the light energy received by the receiving portions; and
conversion means configured to convert the light energy received by the receiving means into electrical energy.

46. A method of generating electrical energy from light energy using the apparatus as defined in claim 45.

47. A method of generating electrical energy from light energy using the apparatus as defined in claim 1.
